(19) United States
(12) Patent Application Publication
(10) Pub. No.: US 2005/0007811 A1
(43) Pub. Date: Jan. 13, 2005

(54) Storage device and data conversion program

(76) Inventor: Seiji Hyoudou, Mishima (JP)

Correspondence Address: SWIDLER BERLIN SHEREFF FRIEDMAN, LLP, 3000 K STREET, NW, BOX IP, WASHINGTON, DC, 20007, US

(21) Appl. No.: 10/856,881

(22) Filed: Jun. 1, 2004

(30) Foreign Application Priority Data
Jun. 4, 2003 (JP) 2003-159091

(51) Int. Cl. G11C 11/22

(52) U.S. Cl. 365/145

(57) ABSTRACT

An attribute for data to be issued is predetermined for each one of a plurality of read routes of a storage device. A data conversion unit identifies the attribute of the data read from the storage device by identifying the particular read route used in the read process and converts the data thus read out into data having the appropriate attribute.

### BACKGROUND OF THE INVENTION

1. Field of the Invention

The present invention relates to a storage device such as a hard disk device, a tape drive, a CD rom, a DVD, a semiconductor memory such as a flash memory or other storage mediums, and a data conversion program for causing the storage device to execute data conversions.

2. Description of the Related Art

In a computer system, data attributes, such as character codes, file formats or language that are handled, vary with, for example, an operating system or an application software, etc. Therefore, a data conversion of data attributes, such as character code conversion, sometimes becomes necessary when data written by a certain host device is to be read by another host device. For such a data conversion, the following technologies have been proposed.

In one method, a host device that reads data from a storage device executes data conversion based on the intelligence provided on the host device (e.g., JP (A) H8-179980).

In another method, data conversion is executed in advance and a plurality of data with different attributes is stored in a storage device.

In yet another method, the user of a host device that issues a read request specifies a data characteristic it wants, and a storage device executes data conversion based on the request (e.g., JP (A) 2001-265631, JP (A) 2002-132566).

JP (A) 2000-347907 discloses a data file automatic conversion device.

However, the abovementioned technologies concerning data conversion have the following problems.

When data conversion is to be conducted based on the intelligence of the host, it requires intelligence and resources for conducting data conversion on the host, thus increasing the load on CPU and storage devices of the host. For example, in order to execute XML (extensible Markup Language), it is said that it requires a memory space of about three times as large as the file size. Moreover, if a plurality of data having various respective data attributes is to be stored in the storage device, the usage of the data keeping area in the storage device increases. Also, if the user is to specify the data attributes that the user wishes to obtain, it puts a big burden on the user.

### SUMMARY OF THE INVENTION

The invention was made in order to solve these problems and its intention is to provide a storage device that is capable of data conversion without requiring intelligence for data conversion on the external device side and an increase of the usage of data storage area in accordance with the execution of the data conversion, while reducing the user's burden for the data conversion, and a data conversion program to cause such a storage device to execute the data conversion.

An embodiment of the present invention provides a storage device having a storage medium and a plurality of read routes for reading data stored in the storage medium in response to a read request from an external device, and further having a data conversion unit. The data conversion unit is for identifying a read route used in the reading, converting the data read out via said read route into data having an attribute predetermined for the identified read route, and issuing it to the external device that requested the reading.

In such an embodiment, the attribute for the data to be issued to the source of the read request is predetermined for each read route. The data conversion unit identifies the attribute of the data to be issued to the source of the read request by identifying the reading route used for reading; and converts the data read out to data having the appropriate attribute. Therefore, there is no need for the user of the external device, which is the source of the read request, to specify the attribute. Also, since the data conversion is made in response to a read request, there is no need to keep multiple data having various attributes on the storage media.

Moreover, there is no need for data conversion on the host, which is the source of the read request, since the data conversion is done at the storage.

Another embodiment of the present invention includes a storage device equipped with a storage medium for storing data, a plurality of writing routes for writing data on the storage medium in response to a writing request received from an external device, and a plurality of read routes for reading data stored in the storage medium in response to a read request from an external device, and further having an attribute keeping unit and a data conversion unit. Each writing route is preset with an attribute, and each writing route writes a data having a predetermined attribute into the storage medium. The attribute keeping unit is for identifying the writing route used in the writing process and keeping the attribute set up for the identified writing route as the one related to the written data. The data conversion unit is for identifying a read route used in the read, converting the data read out via the read route from data having an attribute kept in the attribute keeping unit into data having an attribute predetermined for the identified read route, and issuing it to the external device that requested the reading.

In the above constitution, it is possible to identify the attributes of the data read out and convert the data at the time of the reading, even when the data are written in response to the writing requests from a plurality of writing request sources, since the attributes of the written data are identified and the attributes are kept. Also, the attributes of the written data can be easily identified with a simple constitution as the attributes of the written data are identified by identifying the writing routes used for writing.

Another embodiment of the present invention includes a storage device equipped with a storage medium for storing data, a plurality of writing routes for writing data on the storage medium in response to a writing request received from an external device, and a read route for reading data stored in the storage medium in response to a read request from an external device, and further having an attribute keeping unit and a data conversion unit. Each writing route is associated with a preset attribute, and each writing route writes data having a predetermined attribute into the storage medium. The attribute keeping unit is for identifying the writing route used in the writing process and keeping the attribute set up for the identified writing route as the one related to the written data. The data conversion unit is for converting the data read out via the read route from data having an attribute kept in the attribute keeping unit into data having a predetermined attribute, and issuing it to the external device that requested the reading.

Another embodiment of the present invention includes a data conversion program for causing a storage device having a plurality of reading routes for reading data from a storage medium in response to reading request from an external device to execute a step of identifying the read route used for the read, a step of converting the data read out via the read route into data having an attribute predetermined relative to the identified read route, and a step for issuing the converted data to the external device that requested the reading.

Such an embodiment can also include a data conversion program for causing a storage device having a plurality of writing routes for writing data having an attribute predetermined for each one of the routes based on a request received from an external device and a plurality of read routes for reading data from a storage medium based on a read request received from an external device to execute an attributing keeping step and a data conversion step. The attribute keeping step identifies the writing route used in the writing process and keeps the attribute set up for the identified writing route as the one related to the written data. The data conversion step identifies a read route used in the read, converts the data read out via the read route from data having an attribute kept in the attribute keeping step into data having an attribute predetermined for the identified read route, and outputs it to the external device that requested the reading.

Another embodiment of the present invention includes a data conversion program for causing a storage device having a plurality of writing routes for writing data having an attribute predetermined for each one of the routes based on a request received from an external device and a read route for reading data from a storage medium based on a read request received from an external device to execute an attributing keeping step and a data conversion step. The attribute keeping step identifies the writing route used in the writing process and keeps the attribute set up for the identified writing route as the one related to the written data. The data conversion step converts the data read out via the read route from data having an attribute kept in the attribute keeping step into data having a predetermined attribute, and issues it to the external device that requested the reading.

### BRIEF DESCRIPTION OF THE DRAWINGS

FIG. 1 is a block diagram showing the overall constitution of a system that includes a storage device according to an embodiment of the present invention.

FIG. 2 is a block diagram showing the constitution of a storage device 100.

FIG. 3 is a block diagram showing the functional constitution of a read/write device 120 in accordance with an embodiment of the present invention.

FIG. 4 is a diagram showing a reading attribute table in accordance with an embodiment of the present invention.

FIG. 5 is a flowchart showing the operational procedure of storage device 100 for its reading process in accordance with an embodiment of the present invention.

FIG. 6 is a block diagram showing the overall constitution of a system that includes a storage device according to another embodiment of the present invention.

FIG. 7 is a block diagram showing the constitution of storage device 400.

FIG. 8 is a block diagram showing the functional constitution of a read/write device 420 in accordance with another embodiment of the present invention.

FIG. 9 is a diagram showing a writing attribute table in accordance with another embodiment of the present invention.

FIG. 10 is a flowchart showing the operational procedure of storage device 400 for its writing process in accordance with another embodiment of the present invention.

FIG. 11 is a diagram showing example entries of a writing attribute table in accordance with an embodiment of the present invention.

FIG. 12 is a flowchart showing the operational procedure of storage device 400 for its reading process in accordance with an embodiment of the present invention.

FIG. 13 is a diagram showing the constitution of a tape library device physically equipped with a plurality of writing parts and reading parts embodying the present invention.

### DESCRIPTION OF THE PREFERRED EMBODIMENTS

The preferable embodiments of storage devices and data conversion programs concerning the invention will be described in detail referring to the attached drawings:

A storage device according to an embodiment of the present invention identifies the attribute of the data to be issued to the host device, which is the source of the read request, depending on which reading unit among a plurality of reading units is used in the read process, and issues the data that is read out after converting it into data having the identified attribute.

FIG. 1 is a block diagram showing the overall constitution of the system that includes a storage device according to an embodiment of the present invention. In FIG. 1, the system has a storage device 100, and two host devices 200 and 300. Storage device 100 and host devices 200 and 300 are mutually connected forming a SCSI (Small Computer System Interface) via a bus B. The number of devices and the type of connection interface are not restricted to the above.

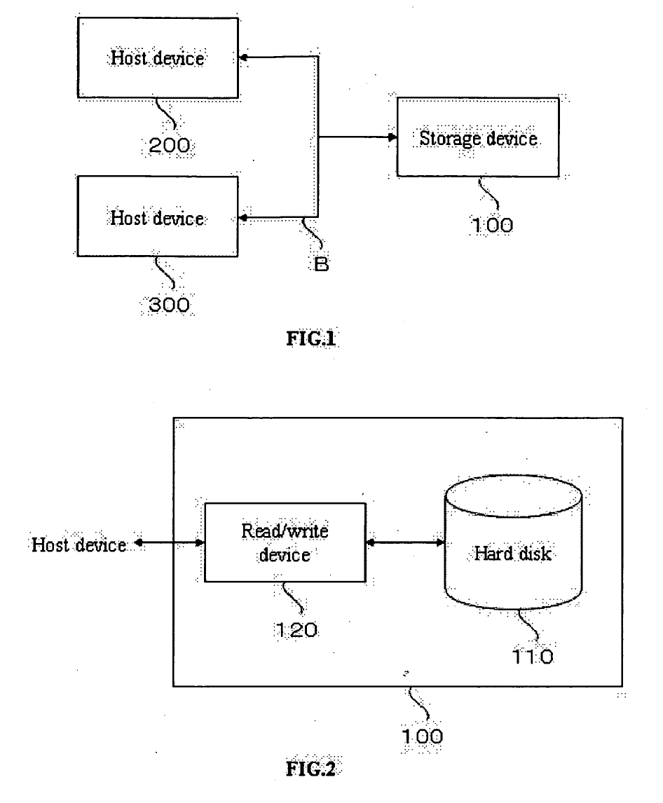

FIG. 2 is a block diagram showing the constitution of storage device 100. In FIG. 2, storage device 100 has a storage medium such as a hard disk 110, for storing data, and a read/write device 120 from or to a storage medium such as hard disk 110 in response to requests from host devices 200 and 300.

Read/write device 120 has a writing route for writing data on hard disk 110 and a read route for reading out data from hard disk 110. Read/write device 120 is equipped with two Logical Unit Numbers (LUN), LUN0 and LUN1. Therefore, read/write device 120 has logically two writing routes, LUN0 and LUN1 as well as two read routes, LUN0 and LUN1. Also, read/write device 120 functions as a data conversion means that provides data conversion to the data read out from hard disk 110 and issues the converted data to host devices 200 and 300.

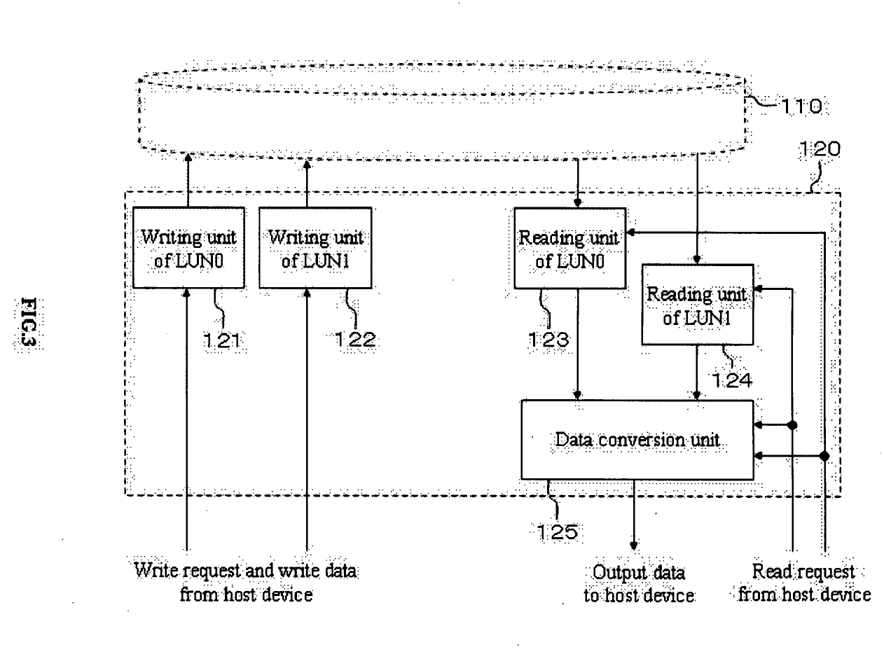

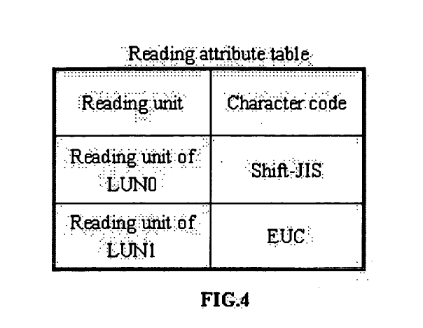

FIG. 3 is a block diagram showing the functional constitution of a read/write device 120 in accordance with an embodiment of the present invention. In FIG. 3, read/write device 120 has a writing unit 121 of LUN0, a writing unit 122 of LUN1, a reading unit 123 of LUN0, a reading unit 124 of LUN1, and a data conversion unit 125. The number of the writing unit is not limited to two, rather it can be 0, 1, 2, 3 or more. The number of reading units is not limited to two, but can be any number as long as it is two or more.

Writing units 121 and 122 write data on a storage medium such as hard disk 110 via a head (not shown) in response to writing requests from host devices 200 and 300.

Reading units 123 and 124 read out data from hard disk 110 via a head (not shown) in response to read requests from host devices 200 and 300. In the disclosed illustrative embodiment, an attribute for data to be issued to the host device is predetermined for each of reading unit 123 of LUN0 and reading unit 124 of LUN1.

Data conversion unit 125 identifies which of the reading units 123 and 124 that is used for the data read operations, converts the data read out by reading units 123 or 124 into data having data attributes in accordance with the identified one of the reading units 123 and 124 according to a predetermined conversion such as the example discussed herein, and issues the data to host devices 200 and 300 that are the sources of the read requests.

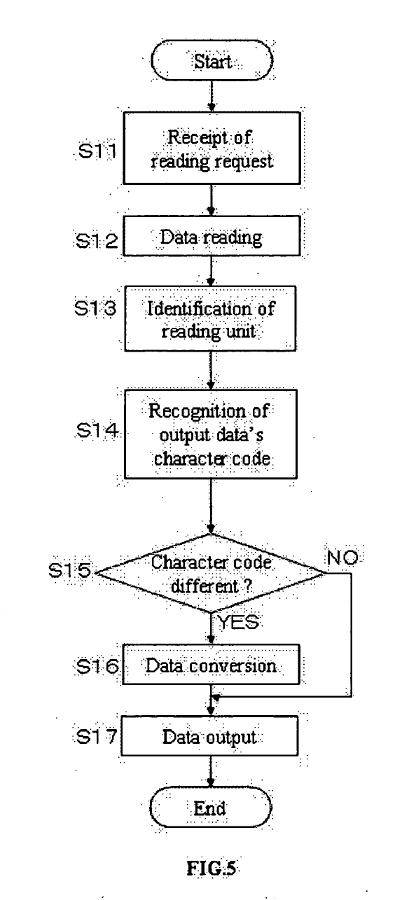

More specifically, data conversion unit 125 has a reading attribute table for storing pairs of a reading unit and an attribute set up for the respective reading unit and a conversion module prepared to convert data stored in hard disk 110 to data having the attributes set up for the respective reading units. Data conversion unit 125 identifies the attributes of the data to be issued based on the identified reading units 123 and 124 by referring to a reading attribute table (e.g., as shown in FIG. 4). The data read out are converted into data having the attributes for the data to be issued by the conversion module, and are issued to the appropriate host device 200 and 300 that is the source of the read request. The setup, modification and other processes for the reading attribute table and conversion module are conducted by through a user interface (not shown), etc.

In order for the above data conversion to be executed, it is necessary for a certain data attribute for the data stored in the storage medium such as hard disk 110 to be specified, but it can be specified by an arbitrary method. For example, only the data having predetermined attributed can be stored in the storage medium such as hard disk 110, or a data attribute can be set up for each area of hard disk 110, or attributes can be specified by analyzing the data read out.

The read/write device 120 includes, for example, a CPU, a ROM, a RAM, an auxiliary memory device. The function that corresponds to the unit is realized by a CPU executing a stored program. More specifically, data conversion unit 125 is realized by the CPU executing a data conversion program in accordance with the present embodiment.

The initial setup for storage device 100 having the above constitution and the operation of storage device 100 provided with the initial setup is described in the following. It is assumed in the following explanation, for illustrative purposes only, that Windows® is used as the operating system of host device 200, and UNIX® is used as the operating system of host device 300. The character code used in Windows is Shift-JIS/and the character code used in UNIX is EUC (Extended UNIX Code). Let us assume that storage device 100 performs character code conversion as the data conversion. Also, it is assumed that only the data whose character code is Shift-JIS is to be stored in storage device 100.

Hereinafter the data whose character code is Shift-JIS will be called Shift-JIS data, and the data whose character code is EUC will be called EUC data.

First, let us describe the initial setup of storage device 100. This initial setup is made by, for example, a system manager. The system manager sets it up so that host device 200 communicates with read/write device 120 of LUN0 and host device 300 communicates with read device 120 of LUN1. This way, host device 200 will be using reading unit 123 of LUN0 and host device 300 will be using reading unit 124 of LUN1. Therefore, the character code of the data to be issued through reading unit 123 of LUN0 will be Shift-JIS, and the character code of the data to be issued through reading unit 124 of LUN1 will be EUC. Therefore, a reading attribute table will be set up as shown in FIG. 4. As an example, the system manager stores data corresponding to FIG. 4 in a conversion module M1, for converting Shift-JIS data into EUC data, in data conversion unit 125.

The read operation of storage device 100 provided with such an initial setup will be described below using an example wherein host device 300 reads data from storage device 100.

FIG. 5 is a flowchart showing the operational procedure of storage device 100 for its reading process in accordance with an embodiment of the present invention. In FIG. 5, when host device 300 issues a read request to read/write device 120 of LUN1, reading unit 124 of LUN1 and data conversion unit 125 receive the reading request (S11). Reading unit 124 of LUN1 reads the data from the storage media such as hard disk 110 in response to the read request and issues the data to data conversion unit 125 (S12). Data conversion unit 125 identifies reading unit 124 of LUN1 as the reading unit that conducted reading based on the read request (S13), and identifies “EUC” as the character code to be issued referencing the read attribute table shown in FIG. 4 (S14). Next, data conversion unit 125 makes a judgment on whether “Shift-JIS” data stored in hard disk 100 is different from the character code of the data to be issued (S 15). It is judged that the character codes are different (S 15: Yes), a conversion module M1 of data conversion unit 125 converts the Shift-JIS data read out into the EUC data to be issued (S 16). It then issues the EUC data to host device 300 that requested the reading (S 17).

When host device 200 reads the data from storage device 100, data conversion unit 125 identifies the character to be issued is Shift-ITS (S 14), and judges that the characters codes are not different from each other (S 15: No). The Shift-JIS data thus read out is issued to host device 200 that requested the reading as is without doing any character conversion (S 17).

The storage device and data conversion program related to the present embodiment have the following effects:

(a) Since the data conversion is done on storage device 100, the loads on the CPU and the storage medium of 110 of the host device in accordance with the data conversion can be alleviated. In other words, the intelligence and resource requirements of the host device for the data conversion can be eliminated.

(b) Since the data conversion is performed during the reading, data with an attribute appropriate for the host device that requested the reading to the host device without having to keep multiple data with various attributes on storage media of 110. Thus, it is possible to avoid an increase of the usage of storage area on storage media of hard disk 110.

(c) If an original data based on an attribute and a converted data based on another attribute that corresponds to the original data are stored on storage media of 110, there is a time lag between the original data's update and the converted data's update, so that there is a chance that the converted data is accessed before it is updated. There is also a chance that the converted data may never be updated due to human errors. However, the above problem does not occur in this embodiment as only the original data is stored and the data is converted when it is read out.

(d) Since the attribute of the data to be issued is identified by identifying, for example, the reading unit that is used for the reading or the host that requested the reading, the data with an appropriate attribute in accordance with the host device that requested the reading can be issued to the host device without having to be instructed by the user of the host device that requested the reading. As a result, the user of the host device that requested the reading can obtain data with an appropriate attribute without any heed to the attribute of the written data or the attribute of the data to be read out. In other words, the burden on the user related to data conversion can be alleviated.

(e) Since the data conversion is done at the time of its reading as needed based on the result of the comparison between the attribute of the data stored in storage media of hard disk 110 and the attribute of the data to be issued, unnecessary data conversion and unnecessary use of the intelligence of storage device 100 can be avoided.

(f) Since the conversion rule such as conversion Table 4 of the data unit 125 can be modified, data can be converted always with the latest conversion rule at the time of reading by constantly updating the conversion rule to the latest version.

A storage device and a data conversion program according to other embodiment of the present invention are substantially identical to those of the first embodiment, except that they determine the attribute of the data written by identifying which writing unit is used to write the data from among a plurality of writing units, store the attribute, and convert the data based on the attribute when the data is read out. The following is the description of such an embodiment using the accompanying drawings, in which the descriptions for those parts overlapping with the first embodiment will be omitted.

FIG. 6 is a block diagram showing the overall constitution of a system that includes a storage device according to an embodiment of the present invention. In FIG. 6, storage device 400 is connected to host devices 200 and 300 in this embodiment.

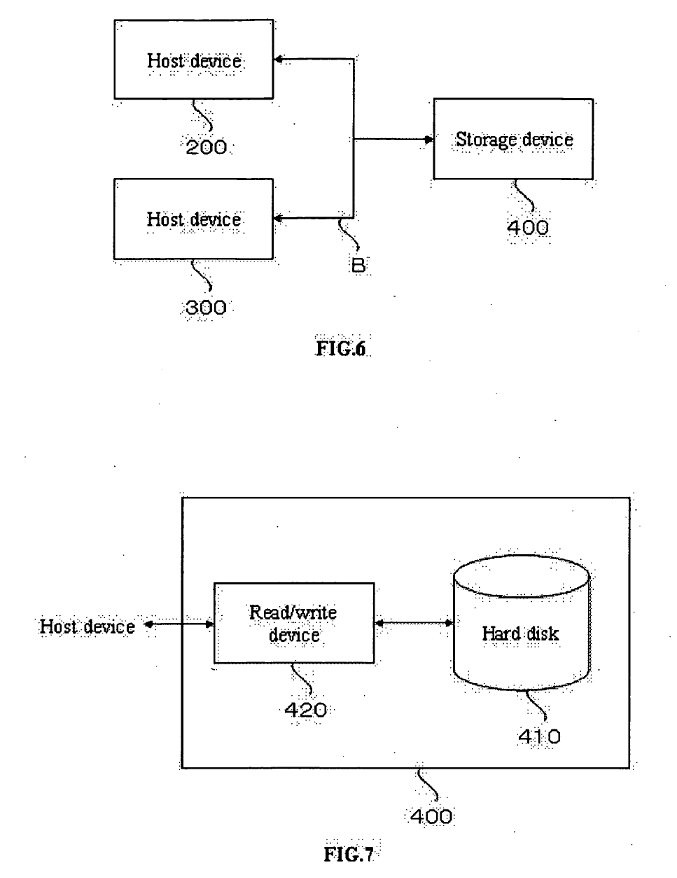

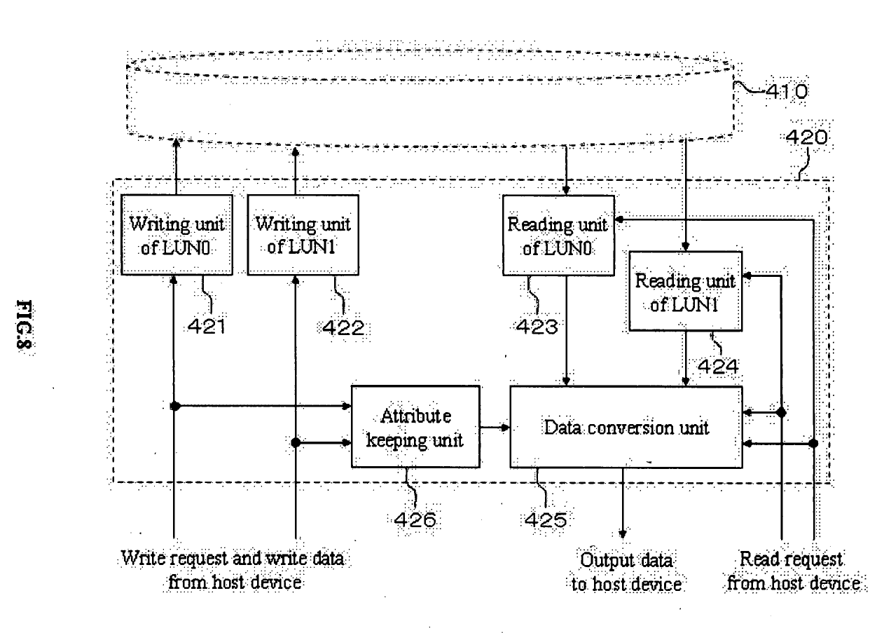

FIG. 7 is a block diagram showing the constitution of storage device 400. In FIG. 7, a read/write device 420 is different from read/write device 120 of the first embodiment in that it functions as an attribute keeping unit for keeping the attributes of the data written in the storage media such as hard disk 410.

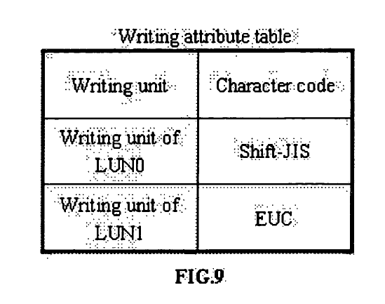

FIG. 8 is a block diagram showing the functional constitution of read/write device 420 in accordance with an embodiment of the present invention. In FIG. 8, read/write device 420 is different from read/write device 120 of the first embodiment in that it is equipped with an attribute keeping unit 426 for identifying the attribute of the written data and keeping the attribute. The number of reading units and writing units is not limited to two, but can be any number as long as it is two or more.

Attributes are preset for a writing unit 421 of LUN0 and a writing unit 422 of LUN1 in this embodiment and writing units 421 and 422 receive data according to the preset attributes from host devices 200 and 300, and write the data into the storage medium such as hard disk 410.

Attribute keeping unit 426 identifies which of the writing units 421 and 422 is used in the writing process and keeps the attribute set up for the identified writing unit 421 or 422 as the one related to the written data. More specifically, attribute keeping unit 426 holds or stores a writing attribute table for keeping pairs of a writing unit and an attribute set up for the writing unit and identifies the attribute for the written data by referencing, for example, a writing attribute table based on which of the writing units 421 and 422 is used in writing. The attribute of the written data is recorded together with the address to which the data is written in the written data attribute keeping table. The setup, modification and other processes for the writing attribute table and conversion module are conducted via, for example, a user interface (not shown), etc.

Reading units 423 and 424 read out data from storage medium such as hard disk 410 in response to read requests from host devices 200 and 300. Reading units 423 and 424 are preset with the attributes of data to be issued to host devices 200 and 300.

Data conversion unit 425 recognizes which one of the reading units, 423 and 424, that is used for reading, converts the data read by either of reading units 423 and 424 from data having an attribute kept in attribute keeping unit 426 into data having an attribute preset for the identified one of reading units 423 and 424 according to a preset conversion rule such as discussed herein based the data in, e.g., the Table of FIG. 9 and the reading unit, and output to one of the host devices 200 and 300 that requested the reading.

More specifically, data conversion unit 425 includes a reading attribute table, such as shown in FIG. 4, for storing pairs of a reading unit and an attribute set up in the reading unit and a conversion module prepared beforehand for converting data having an attribute set up in each writing unit to data having an attribute set up for each readout unit. Data conversion unit 425 identifies the attribute of the data read out based on the address of the data read out by referencing the written data attribute keeping table kept in attribute keeping unit 426, such as shown in FIG. 4.

Data conversion unit 425 identifies the attribute of the data to be issued based on the identified reading unit 423 or 424 by referring to the reading attribute table. The data read out is converted into data having the attribute to be issued according to the attribute of the data read out and the attribute of the data to be issued by the conversion module and issued to host device 200 or 300 that requested the reading. The setup, modification and other processes for the readout attribute table and conversion module can be implemented via, for example, a user interface (not shown), etc.

More specifically, attribute keeping unit 426 and data conversion unit 425 are realized by a CPU executing a data conversion program according to the present embodiment.

The initial setup for storage device 400 having the above constitution and the operation of storage device 400 provided with the initial setup will be described in the following. It is assumed in the following explanation that Windows® is used as the operating system of host device 200, and UNIX® is used as the operating system of host device 300. It is also assumed that storage device 400 is to convert character codes between Shift-JIS and EUC as a data conversion process. Different from the first embodiment, both host devices 200 and 300 can write data to storage media such as hard disk 410 in this embodiment. In other words, Shift-JIS and EUC data are written to hard disk 410.

First, let us describe the initial setup of storage device 400. The system manager sets it up so that host device 200 communicates with read/write device 420 of LUN0 and host device 300 communicates with read/write device 420 of LUN1. This way, host device 200 will be using writing unit 421 of LUN0 and host device 300 will be using writing unit 422 of LUN1. Therefore, the character code of the data written by writing unit 421 of LUN0 becomes Shift-JIS and the character code of the data written by writing unit 422 of LUN1 becomes EUC. Therefore, a writing attribute table will be set up as shown in the example of FIG. 9. This way, host device 200 will be using reading unit 423 of LUN0 and host device 300 will be using reading unit 424 of LUN1. Therefore, the character code of the data to be issued through readout unit 423 of LUN0 will be Shift-JIS, and the character code of the data to be issued through readout unit 424 of LUN1 will be EUC. Therefore, a readout attribute table will be set up as shown in FIG. 4. The system manager stores the appropriate table data in conversion module M1 for converting Shift-JIS data into EUC data as well as in conversion module M2 for converting EUC data into Shift-JIS data, into data conversion unit 425.

The writing operation of storage device 400 provided with the initial setup will be described below using an example wherein host device 200 writes data into storage device 400.

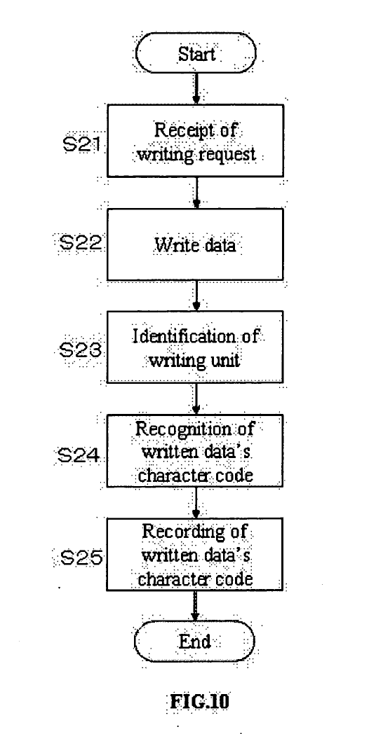

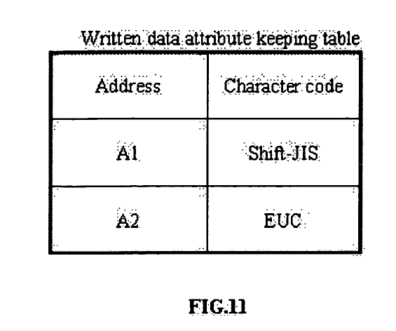

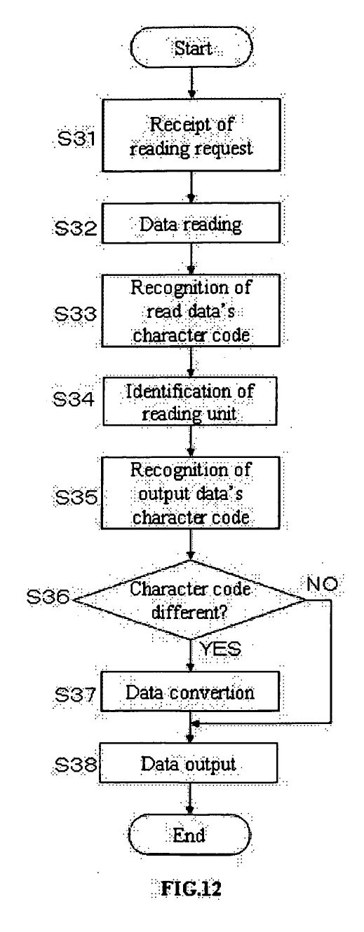

FIG. 10 is a flowchart showing the operational procedure of storage device 400 for its writing process in accordance with an embodiment of the present invention. In FIG. 10, when host device 200 issues a write request to read/write device 420 of LUN0 specifying a writing address A1, writing unit 421 of LUN0 and attribute keeping unit 426 accept the write request (S21). Writing unit 421 of LUN0 writes Shift-JIS data received from host device 200 to address A1 to the storage media, such as hard disc 410 (S22). Attribute keeping unit 426 identifies that the writing unit that performed the writing is writing unit 421 of LUN0 based on the write request (S23). Therefore, it identifies the character code of the written data as Shift-JIS referencing the writing attribute table shown in FIG. 9 (S24), and records Shift-JIS tagged with address A1 in the written data attribute keeping table as shown in FIG. 11 (S25).

The same type of operation occurs when host device 300 issues a write request specifying address A2, storage device 400 records character code EUC tagged with address A2 in written data attribute keeping table as shown in FIG. 11.

Next, the operational procedure of storage device 400 for its reading process will be described below using an example wherein host device 300 is to read the data written on address A1 from storage device 400.

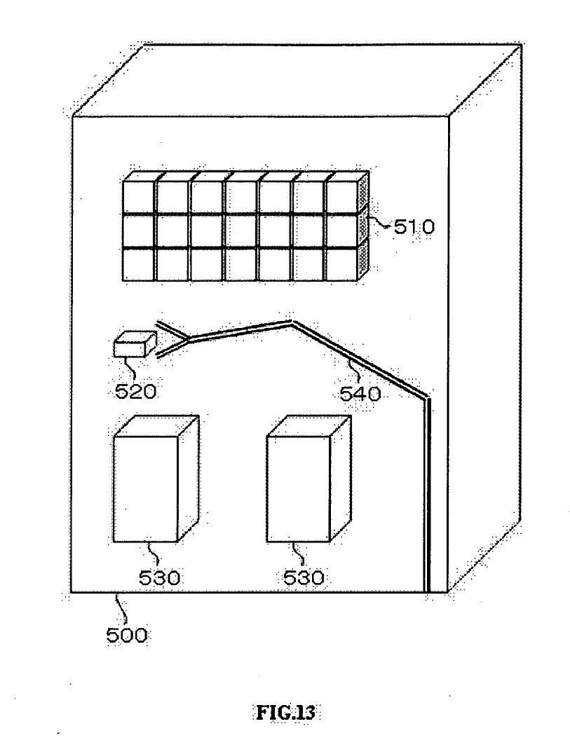

FIG. 12 is a flowchart showing an example of an operational procedure of storage device 400 during its reading process in accordance with an embodiment of the present invention. In FIG. 12, when host device 300 issues a read request to read/write device 420 of LUN1 specifying a reading address Al, reading unit 424 of LUN1 and data conversion unit 425 accept said read request (S31). Reading unit 424 of LUN1 reads data from address A1 of the storage device such as hard disk 410 and issues the data to data conversion unit 425 (S32). Data conversion unit 425 identifies the address of the data read out as address A1 based on the read request, and identifies the character code of the data read out is Shift-JIS referencing the written data attribute keeping table shown in FIG. 11 (S33). Data conversion unit 425 identifies reading unit 424 of LUN1 as the read unit that conducted reading based on the read request (S34), and identifies “EUC” as the character code to be issued referencing the read attribute table shown in FIG. 4 (S35). Next, data conversion unit 425 makes a judgment on whether the character code of the data read out is different from the character code of the data to be issued (S36). Since the character codes are judged to be different (S36: Yes), i.e., the character code of the data read out being Shift-JIS and the character code of the data to be issued being EUC, the Shift-JTS data read out is converted into EUC data to be issued by means of conversion module M1 (S37). It then issues the EUC data to host device 300 that requested the reading (S38).

When host device 200 issues a read request specifying address A1, data conversion unit 425 identifies the character to be issued is Shift-JTS (S35), and judges that the characters codes are not different from each other (S36: No). The Shift-JIS data thus read out is issued to host device 200 as is without doing any character conversion (S38).

When host device 200 issues a read request specifying a readout address A2, data conversion unit 425 converts EUC data into Shift-JTS data by means of conversion module M2 since the character code of the data read out is EUC and the character code of the data to be issued is Shift-JIS (S37).

The storage device and the data conversion program according to this embodiment provides the following effects in addition to the effects (a) through (f) of the first embodiment:

(g) It can identify the attribute of the data read out and convert the data, even when the data are written in response to the writing requests from a plurality of writing request sources, since the attributes of the written data are kept tagged with the data written. Thus, it can store data with various attributes on a storage medium such as hard disk 410.

(h) The attributes of the written data can be easily identified with a simple constitution as the attributes of the written data are identified by identifying the writing units used for writing. Also, the burden on the user of the host device that requested the writing can be alleviated as it is possible to identify the attribute of the written data without having to have any instruction on the attribute from the host device that requested the writing.

The invention is not limited by the first and second embodiments described above. For example, the data attributes are not limited to character codes, but rather can be file types and languages, and the data conversions can be file type conversions, language conversions, etc. The applicable file types include, for example, OASYS, Word, TEXT, CSV (Comma Separated Value) and XML (eXtensible Markup Language) types, or any other file type, while the applicable languages include English and Japanese or any other language.

The storage device is not limited to the hard disk but can be other external memory devices such as the tape library. The writing and reading units can be not only logically but also physically plural. FIG. 13 is a diagram showing the constitution of a tape library device physically equipped with a plurality of writing parts and reading parts.

In FIG. 13, a tape library device 500 is equipped with a plurality of magnetic tapes 520 stored in a tape warehouse 510, a plurality of tape drives 530 that write to or read from the magnetic tapes 520, and a robot arm 540 for moving magnetic tapes 520 between tape warehouse 510 and tape drive 530. Since each tape drive 530 includes a writing unit and a reading unit, tape library device 500 is physically equipped with a plurality of writing units and reading units. In such a tape library device 500, if each reading unit is set up with an attribute and a data conversion unit is provided, a storage device similar to the first embodiment can be constituted. Moreover, if each writing unit is set up with an attribute and an attribute keeping unit is provided, a storage device similar to the second embodiment can be constituted.

It is possible to have only one reading unit in the second embodiment. In such a case, the attribute of the data to be issued can be specified by an appropriate method, for example, by being preset to a certain attribute. In such an example, FIG. 12, steps S34 and S35 can be omitted in that case.

According to this invention, no intelligence for data conversion is needed on the external device as the data conversion is done at the storage device. Also, since the data conversion is done in response to a readout request, there is no need to keep multiple data having various attributes, so that it can avoid the increase of the data storage area usage.

Moreover, it is unnecessary for the user to specify the attribute so that the user's burden can be reduced, since it is possible to identify the attribute of the data to be issued to the external device that is requesting the reading by means of identifying the reading route used for the reading and converting the read data to the data having the appropriate attribute.

1. A storage device comprising:
a storage medium for storing data;
a plurality of read routes operatively connected to the storage medium so as to provide data from the storage medium;
a data conversion unit operatively connected to alt least some of the read routes so as to selectively convert data provided from the storage medium into data having a predetermined attribute.

2. A storage device according to claim 1, wherein the plurality of read routes are further operatively connectable to receive respective read requests, and wherein the data conversion unit is operatively connected to determine the predetermined attribute based on a read request.

3. A storage device according to claim 2, further comprising:
a plurality of writing routes having corresponding attributes and being operatively connectable to receive respective write requests so as to provide data to the storage medium;
an attribute keeping unit operatively connected to at least some of the writing routes so as to store attributes corresponding to selected ones of the at least some of the writing routes; and
wherein the data conversion unit is operatively connected to the attribute keeping unit so as to selectively convert data read in response to a read request, based on an attribute corresponding to the read request and on a selected one of the attributes stored in the attribute keeping unit.

4. A data conversion method for accessing a storage device including a plurality of read routes each having a corresponding attribute, and a storage medium operatively connected to the read routes, comprising:
storing a plurality of attributes;
reading data from the storage medium;
converting the data read from the storage medium to data having a predetermined attribute.

5. A data conversion program according to claim 4, further comprising:
receiving a read request at a read route;
identifying the read route that received the read request; and
determining the predetermined attribute based on the identified read route.

6. A data conversion program according to claim 5, wherein the storage device further includes a plurality of write routes each having a corresponding attribute, further comprising:
receiving a write request:
identifying an attribute associated with the write request; and wherein
the determining is further based on the identified attribute associated with the write request.
